(19) United States
(12) Patent Application Publication
(10) Pub. No.: US 2025/0192095 A1
(43) Pub. Date: Jun. 12, 2025

(54) SEMICONDUCTOR PACKAGE AND METHOD FOR FABRICATING SEMICONDUCTOR PACKAGE

(71) Applicant: TRON FUTURE TECH INC., HSINCHU CITY (TW)

(72) Inventors: KUAN-NENG CHEN, HSINCHU CITY (TW); HAN-WEN HU, HSINCHU CITY (TW); MING-WEI WENG, HSINCHU CITY (TW)

(21) Appl. No.: 18/963,318

(22) Filed: Nov. 27, 2024

Related U.S. Application Data
(60) Provisional application No. 63/607,565, filed on Dec. 8, 2023.

(51) Int. Cl. H01L 23/00

(52) U.S. Cl. CPC H01L 24/73; H01L 24/16; H01L 24/29; H01L 24/32; H01L 24/81; H01L 24/83; H01L 24/92; H01L 2224/16227; H01L 2224/26175; H01L 2224/29082; H01L 2224/2919; H01L 2224/32225; H01L 2224/73204; H01L 2224/81191; H01L 2224/81935; H01L 2224/83007; H01L 2224/83104; H01L 2224/83192; H01L 2224/83935; H01L 2224/9211

(57) ABSTRACT

A method for fabricating a semiconductor package includes applying polymer-based solder paste onto a substrate; bringing a plurality of solder bumps on a semiconductor die into contact with the polymer-based solder paste on the substrate; reflowing the polymer-based solder paste to form a plurality of solder joints between the substrate and the semiconductor die, wherein a post-soldering residue is produced to encapsulate a lower portion of each solder joint; and applying an underfill between the substrate and the semiconductor die to encapsulate an upper portion of the solder joint.

### PRIORITY CLAIM AND CROSS-REFERENCE

The present application claims priority to U.S. Provisional Patent Applications including Ser. No. 63/607,565, filed on Dec. 8, 2023, which is incorporated by reference herein in its entirety.

### BACKGROUND

The present disclosure relates to semiconductor packaging and, more particularly, to a method for fabricating a semiconductor package without the use of flux cleaning, and a semiconductor package.

As the technology advanced, semiconductor packaging now plays a crucial role in enhancing device performance through improved thermal management, mechanical support, and signal integrity. Modern packaging technologies offer numerous advantages, including enhanced protection from physical and chemical degradation, efficient heat dissipation, and reduced signal interference, all contributing to the overall reliability and performance of electronic devices. There are various types of semiconductor packages, such as through-hole packages, surface-mount packages, and advanced forms like ball grid array (BGA) and chip-scale packages (CSP). Each type can be tailored to offer a balance between size, cost and performance to thereby meet different application needs. The development of packaging technologies continues to play a pivotal role in the miniaturization and performance optimization of electronic products.

### SUMMARY

The described embodiments provide a method for fabricating a semiconductor package without the use of flux cleaning, and a semiconductor package.

Some embodiments described herein may include a method for fabricating a semiconductor package. The method includes applying polymer-based solder paste onto a substrate; bringing a plurality of solder bumps on a semiconductor die into contact with the polymer-based solder paste on the substrate; reflowing the polymer-based solder paste to form a plurality of solder joints between the substrate and the semiconductor die, wherein a post-soldering residue is produced to encapsulate a lower portion of each solder joint; and applying an underfill between the substrate and the semiconductor die to encapsulate an upper portion of the solder joint.

Some embodiments described herein may include a method for fabricating a semiconductor package. The method includes applying solder paste comprising a predetermined polymer material onto a substrate; bringing a plurality of solder bumps on a semiconductor die into contact with the solder paste on the substrate; reflowing the solder paste to form a plurality of solder joints between the substrate and the semiconductor die; and applying an underfill comprising the predetermined polymer material between the substrate and the semiconductor die to encapsulate the solder joints.

Some embodiments described herein may include a semiconductor package. The semiconductor package includes a substrate, a semiconductor die, a plurality of solder joints, a post-soldering residue and an underfill. The solder joints are electrically connected between the substrate and the semiconductor die. The post-soldering residue includes a predetermined polymer material, and is formed on the substrate to encapsulate a lower portion of each solder joint. The underfill includes the predetermined polymer material, and is formed between the semiconductor die and the post-soldering residue to encapsulate an upper portion of each solder joint.

With the use of the proposed packaging scheme, fine-pitch solder joints can be partially encapsulated by a post-soldering residue of polymer-based solder paste, the underfill injection step can be performed without the need for flux cleaning, and a uniform underfill with low-bubble ratio can be achieved. As the use of expensive fine-pitch cleaning equipment and procedures can be omitted, the proposed packaging scheme can reduce the process costs of fine-pitch WLCSP packaging. In addition, the proposed packaging scheme can allow simultaneous assembly of components without solder balls/bumps (e.g. passive or large components), further reducing process costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram illustrating an exemplary semiconductor package in accordance with some embodiments of the present disclosure.

FIG. 2 is a flow chart of an exemplary method for fabricating a semiconductor package in accordance with some embodiments of the present disclosure.

FIG. 3 is a diagram illustrating polymer-based solder paste applied onto the substrate shown in FIG. 1 in accordance with some embodiments of the present disclosure.

FIG. 4 is a diagram illustrating solder bumps used to forming the solder joints shown in FIG. 1 in accordance with some embodiments of the present disclosure.

FIG. 5 is a diagram illustrating a post-soldering residue partially encapsulating the solder joints shown in FIG. 1 in accordance with some embodiments of the present disclosure.

FIG. 6 is a diagram illustrating an underfill partially encapsulating the solder joints shown in FIG. 1 in accordance with some embodiments of the present disclosure.

FIG. 7 illustrates an exemplary scanning electron microscope image of a partial structure of the semiconductor package shown in FIG. 1 in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the present disclosure may repeat reference numerals and/or letters in the various examples. This repetition is for the purpose of simplicity and clarity and does not in itself dictate a relationship between the various embodiments and/or configurations discussed.

Further, it will be understood that when an element is referred to as being “connected to” or “coupled to” another element, it may be directly connected to or coupled to the other element, or intervening elements may be present.

Moreover, spatially relative terms, such as “below,” “above,” “left,” “right,” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

To enhance production capacity and reduce costs, the wafer level chip scale package (WLCSP) on panel technology is utilized to package chips on a panel/substrate larger than a wafer. The WLCSP on panel technology can establish electrical connections between the chip and the substrate using flux, and strengthen the structure by applying an underfill. However, acidic substances in flux residues can affect the reliability of subsequent products, necessitating a cleaning process to remove the flux residues before applying the underfill. In fine-pitch WLCSP packaging, the narrow solder bump pitch makes cleaning flux residues more challenging. This challenge often necessitates the use of fine-pitch cleaning equipment that can precisely control the angle between the nozzle and the substrate, which significantly increases cleaning costs.

One possible method to reduce cleaning costs is to apply low-residue flux to the chip, which can reduce or eliminate post-solder cleaning operations. Given the relatively low activity of low-residue flux has, the solder bumps/balls on the chip, which exhibit high solderability and reactivity, have to be adequately coated with low-residue flux and reflowed to establish electrical connections between the chip and the substrate. In other words, the application of low-residue flux is limited to chips with solder bumps or solder balls. In addition, low-residue flux may exhibit lower wetting performance, which can impact the formation of reliable solder joints.

The present disclosure describes exemplary methods for fabricating semiconductor packages, each of which utilizes polymer-based solder paste to form a structure having fine-pitch solder joints (e.g. solder joints in fine-pitch WLCSP packages) that are partially encapsulated. The underfill process can be performed without the need for flux cleaning. The polymer-based solder paste may include a polymer material (e.g. epoxy resin), which can act as an adhesive that cures after soldering to form a protective layer. In some embodiments, the proposed method can apply to component packaging without solder bumps/balls. This can enable chips with fine-pitch solder bumps/balls to be assembled simultaneously with passive components or large components, thereby reducing process costs. Further description is provided below.

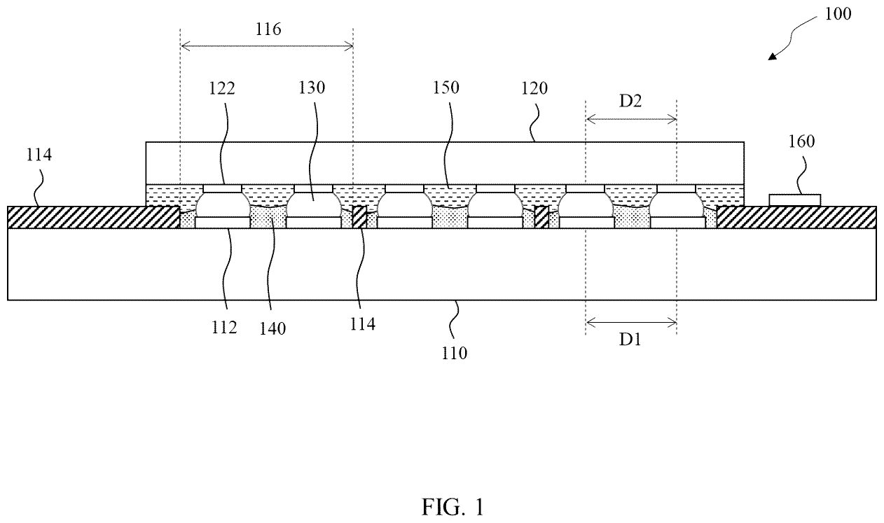

FIG. 1 is a diagram illustrating an exemplary semiconductor package in accordance with some embodiments of the present disclosure. The semiconductor package 100 may be a fine-pitch WLCSP, or another package structure meeting the requirements of high packaging density and high performance. The semiconductor package 100 includes, but is not limited to, a substrate 110, a semiconductor die (or a chip) 120, a plurality of solder joints 130, a post-soldering residue 140, and an underfill 150.

The substrate 110 can be, but is not limited to, a semiconductor substrate (e.g. a silicon substrate), a glass substrate, a substrate used in WLCSP on panel packaging, or other types of package substrates. In some embodiments, the substrate 110 may be an interposer used for 2.5D packaging, in which multiple dies or chips are mounted on the substrate 110 to implement high-density interconnections. In some embodiments, the substrate 110 may be a printed circuit board substrate or other types of circuit board substrates.

The semiconductor die 120 may be a complementary metal-oxide semiconductor (CMOS) integrated circuit (IC) chip, a radio-frequency (RF) chip, or other types of IC chips. The solder joints 130 are electrically connected between the substrate 110 and the semiconductor die 120. In the present embodiment, the solder joints 130 are located on pads 122 of the semiconductor die 120. A pitch D2 between adjacent pads 122 can be less than or equal to 200 um, indicating that the semiconductor die 120 can be a die having fine-pitch pads. Additionally or alternatively, the solder joints 130 are located on pads 112 of the substrate 110. A pitch D1 between adjacent pads 112 can be less than or equal to 200 μm. In some embodiments, the pads 122 and the pads 112 may be aligned or substantially aligned.

The post-soldering residue 140 is formed on one side of the substrate 110 to encapsulate a lower portion of each solder joint 130. The post-soldering residue 140 may include a predetermined polymer material, and partially encapsulate the solder joint 130 to increase its mechanical strength and reliability. The post-soldering residue 140 can be a cured residue that would not require subsequent cleaning. Compared with a post-soldering residue from general-purpose solder paste (e.g. rosin-based solder paste) which contains acidic substances, the post-soldering residue 140 can be a cured residue from polymer-based solder paste, and provide excellent mechanical support and structural stability.

The underfill 150 is formed between the semiconductor die 120 and the post-soldering residue 140 to encapsulate an upper portion of each solder joint 130. The underfill 150 may be a polymer-based material, and used for reducing the effects of thermal stress, mechanical stress, and environmental factors (e.g. humidity, contamination, and chemical corrosion) on the solder joints 130. In the present embodiment, both the underfill 150 and the post-soldering residue 140 may include the predetermined polymer material, providing substantially uniform stress distribution on the solder joints 130 and ensuring the reliability of the semiconductor package 100. By way of example but not limitation, the predetermined polymer material may include epoxy resin. Note that the underfill 150 can be directly applied between the semiconductor die 120 and the post-soldering residue 140 without removing the post-soldering residue 140.

In the present embodiment, the semiconductor package 100 may further include a solder mask 114 formed on the substrate 110 with one or more openings 116. Each opening 116 accommodates one or more solder joints 130. Within each opening 116, an area on the substrate 110 between adjacent solder joints 130 can covered with the post-soldering residue 140. In other words, in a region that is located between the substrate 110 and the semiconductor die 120 and corresponds to the opening 116, the lower and upper portions of the region may be filled with the post-soldering residue 140 and the underfill 150, respectively, to encapsulate the solder joints 130.

Note that the structure shown in FIG. 1 is provided for illustrative purposes, and is not intended to limit the scope of the present disclosure. For example, the number of openings in the solder mask 114 and/or the number of solder joints accommodated in each opening may be determined based on design requirements. Those skilled in the art will understand that other packaging structures using a polymer-based post-soldering residue and an underfill to encapsulate solder joints are within the scope of the present disclosure.

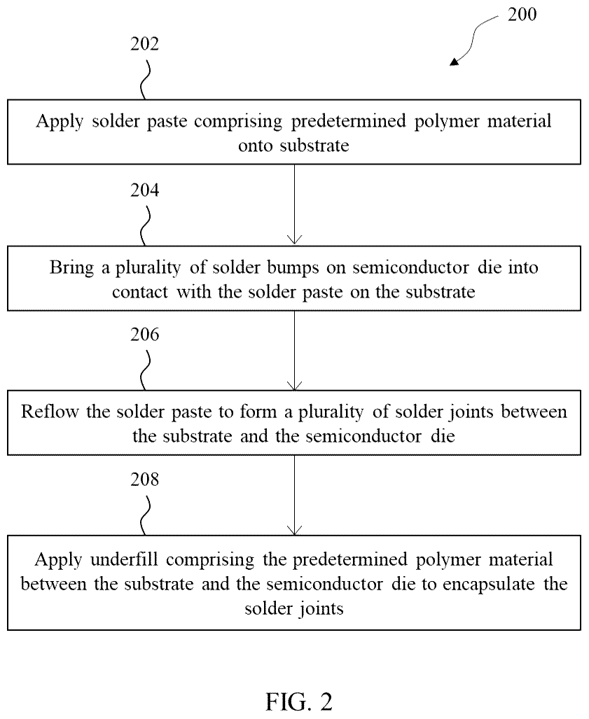

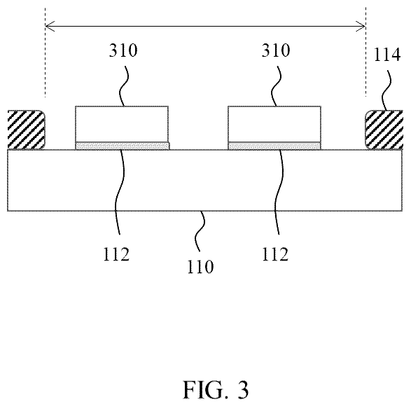

FIG. 2 is a flow chart of an exemplary method for fabricating a semiconductor package in accordance with some embodiments of the present disclosure. For illustrative purposes, the method 200 shown in FIG. 2 is described below with reference to different stages of fabricating the semiconductor package 100 shown in FIG. 1. FIG. 3 to FIG. 6 can serve as embodiments of different stages of fabricating the semiconductor package 100 shown in FIG. 1. However, this is not intended to limit the scope of the present disclosure. The method 200 can be used to fabricate other semiconductor package structures (e.g. fine-pitch WLCSP on panel packaging) without departing from the scope of the present disclosure.

Firstly, referring to FIG. 3 and also to FIG. 2, in step 202, polymer-based solder paste 310 (e.g. solder paste including a predetermined polymer material) is applied onto the substrate 110. By way of example but not limitation, stencil printing or other coating methods can be used to apply the polymer-based solder paste 310 onto the pads 112, which are located within the openings 116 of the solder mask 114. In the present embodiment, the polymer-based solder paste 310 may be epoxy-based solder paste or solder paste containing epoxy resin. In other words, the predetermined polymer material may include epoxy resin. However, this is not intended to limit the scope of the present disclosure. In some embodiments, the polymer-based solder paste 310 may be a polymer-based solder paste that, after curing, can provide sufficient mechanical support and high-temperature resistance.

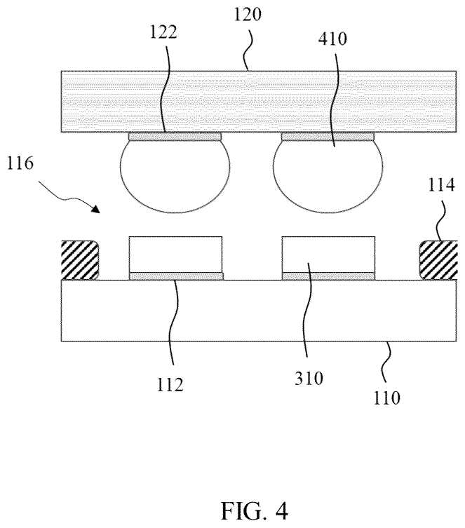

Next, referring to FIG. 4 and also to FIG. 2, in step 204, solder bumps (or solder balls) 410 on the semiconductor die 120 are brought into contact with the polymer-based solder paste 310 on the substrate 110. The semiconductor die 120 can be picked and placed above the substrate 120. The solder bumps 410 on the pads 122 are aligned with the pads 112 on the substrate 110. By way of example but not limitation, the center points of the pads 122 can be substantially aligned with the center points of the pads 112. In the present embodiment, the semiconductor die 120 may have fine-pitch pads or fine-pitch solder bumps. For instance, the distance between adjacent pads 122 can be less than or equal to 200 μm. Additionally or alternatively, the pads 112 on the substrate 110 may also have a fine pitch, such as a pitch of less than or equal to 200 μm. In some cases where the pads 122/112 have a fine pitch, the solder bump 410 can correspondingly have a small size, such as a diameter of less than or equal to 100 μm.

Note that in fine-pitch packaging applications, the pitch of the pads 112, the pitch of the pads 122, and/or the pitch of the solder bumps 410 are all relatively small. In some embodiments, the amount of the polymer-based solder paste 310 applied in step 202 can be determined according to the pitch of the pads 112, the pitch of the pads 122, and/or the pitch of the solder bumps 410, thereby avoiding short circuits caused by excessive solder paste application amount.

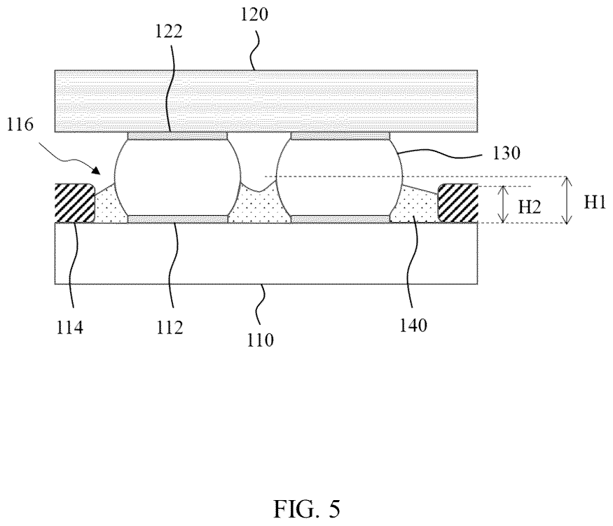

Referring to FIG. 5 and also to FIG. 2, in step 206, the polymer-based solder paste 310 is reflowed to form one or more solder joints 130 between the substrate 110 and the semiconductor die 120. The solder joints 130 are arranged to electrically connect the pads 112 to the pads 122. In the present embodiment, the solder joints 130 may be formed within the openings 116. In addition, after the polymer-based solder paste 310 is reflowed, the post-soldering residue 140 can be produced to partially encapsulate each solder joint 130, thereby protecting the solder joint 130. For instance, the post-soldering residue 140 can be produced on the substrate 110 to encapsulate a lower portion of the solder joint 130.

In some embodiments, as the post-soldering residue 140 is a cured product of the polymer-based solder paste 310 resulting from the reflow process, the post-soldering residue 140 may include polymer material(s) and have sufficient mechanical support and high-temperature resistance properties. In some embodiments, the post-soldering residue 140 may include the predetermined polymer material (e.g. epoxy resin) contained in the solder paste 310 shown in FIG. 4. In some embodiments, the maximum thickness H1 of the post-soldering residue 140 may be greater than or equal to the maximum thickness H2 of the solder mask 114. In some embodiments, the post-soldering residue 140 can protect the area on the substrate 110 that is not covered with non-solder mask defined (NSMD) pads. For example, within the opening 116, the post-soldering residue 140 can cover an area on the substrate 110 between adjacent solder joints 130. Similarly, within the opening 116, the post-soldering residue 140 can cover an area on the substrate 110 between the solder joint 130 and the solder mask 114 that are adjacent to each other.

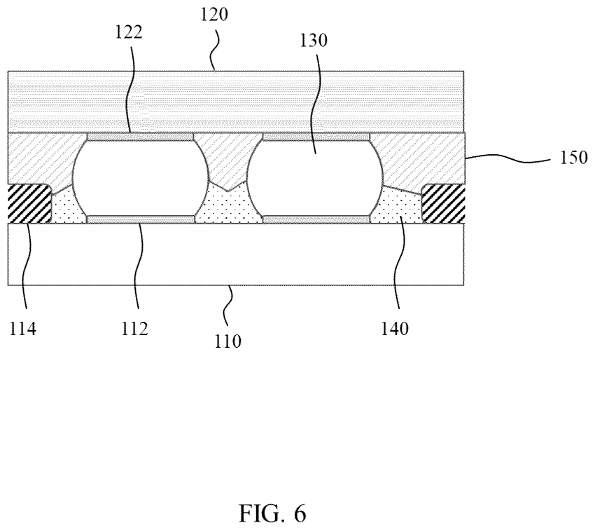

As the post-soldering residue 140 would not interfere with or impede the capillary flow of the underfill, the underfill can be applied without cleaning operations after the reflow process. Referring to FIG. 6 and also to FIG. 2, in step 208, the underfill 150 is applied or injected between the substrate 110 and the semiconductor die 120 to encapsulate the solder joints 130. In the present embodiment, the underfill 150 may encapsulate an upper portion of each solder joint 130. For example, a gap between the semiconductor die 120 and the post-soldering residue 140 can be filled with the underfill 150 to encapsulate an upper portion of each solder joint 130.

The underfill 150 may include polymer material(s) to provide sufficient mechanical support and high-temperature resistance. In some embodiments, the underfill 150 and the post-soldering residue 140 shown in FIG. 5 may include the same polymer material, such as epoxy resin. In some embodiments, the underfill 150 and the polymer-based solder paste 310 shown in FIG. 3 may include the same polymer material, such as epoxy resin.

By forming the post-soldering residue 140 that contains polymer material(s) to partially encapsulate the solder joints 130, it is possible to fill the underfill 150 in packaging structures with small solder joint pitches (e.g. fine-pitch WLCSP packaging structures) without the need of fine-pitch cleaning equipment. In addition, after the underfill injection step is completed, the solder joints 130 (e.g. fine-pitch solder joints) encapsulated by the post-soldering residue 140 and the underfill 150 can pass various tests, such as a high and low temperature test, a high-temperature high-humidity (HTHH) storage test, a thermal cycling test (TCT), or other types of tests. Semiconductor packages fabricated using the proposed method can maintain high reliability even if the pitch between solder joints is very small.

Consider an example where large solder balls (e.g. solder balls with a diameter greater than or equal to 250 μm) are reflowed to form solder joints. An adequate amount of polymer-based solder paste can be applied to solder pads to form solder joints, and a post-soldering residue that fully encapsulates the entire solder ball can be formed. The formed solder joints can provide sufficient mechanical support, thus eliminating the need for an underfill injection step. In contrast, solder joints formed from small solder balls are relatively small, and may need an underfill to enhance reliability. Thus, an appropriate amount of polymer-based solder paste can be applied to form the post-soldering residue 140 that not only can protect the solder joints 130 and the area not covered by NSMD pads, but also can leave sufficient space for the underfill 150 to improve the overall reliability of the package structure.

Moreover, as the proposed packaging scheme can apply polymer-based solder paste onto the conductive areas on the substrate (rather than solder balls or solder bumps) and eliminate the need for flux cleaning, a passive component (e.g. the passive component 160 shown in FIG. 1) can be assembled simultaneously on the substrate 120. By way of example but not limitation, the passive component can be a power divider, a connector, or a capacitor.

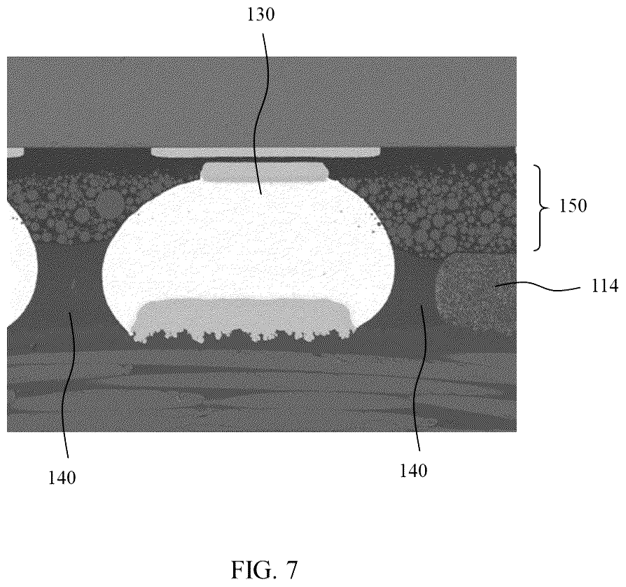

FIG. 7 illustrates an exemplary scanning electron microscope (SEM) image of a partial structure of the semiconductor package 100 shown in FIG. 1 in accordance with some embodiments of the present disclosure. In the embodiment shown in FIG. 7, the post-soldering residue 140 can be a residue of epoxy-based solder paste, and the underfill 150 can have properties similar to those of the post-soldering residue 140. The epoxy resin matrix in the underfill 150 appears as a continuous phase with smooth regions in the SEM image, and the filler contained in the underfill 150 appears as brighter regions in the SEM image. The post-soldering residue 140 and the underfill 150 encapsulate the lower and upper portions of the solder joints 130 respectively to ensure high reliability.

With the use of the proposed packaging scheme, fine-pitch solder joints can be partially encapsulated by a post-soldering residue of polymer-based solder paste, the underfill injection step can be performed without the need for flux cleaning, and a uniform underfill with low-bubble ratio can be achieved. As the use of expensive fine-pitch cleaning equipment and procedures can be omitted, the proposed packaging scheme can reduce the process costs of fine-pitch WLCSP packaging. In addition, the proposed packaging scheme can allow simultaneous assembly of components without solder balls/bumps (e.g. passive or large components), further reducing process costs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for fabricating a semiconductor package, comprising:
applying polymer-based solder paste onto a substrate;
bringing a plurality of solder bumps on a semiconductor die into contact with the polymer-based solder paste on the substrate;
reflowing the polymer-based solder paste to form a plurality of solder joints between the substrate and the semiconductor die, wherein a post-soldering residue is produced to encapsulate a lower portion of each solder joint; and
applying an underfill between the substrate and the semiconductor die to encapsulate an upper portion of the solder joint.

2. The method of claim 1, wherein each of the post-soldering residue and the underfill comprises a predetermined polymer material.

3. The method of claim 2, wherein the predetermined polymer material comprises epoxy resin.

4. The method of claim 1, wherein the solder joint are formed within an opening of a solder mask on the substrate; within the opening, an area on the substrate between adjacent solder points is covered with the post-soldering residue.

5. The method of claim 1, wherein the solder joints are formed within an opening of a solder mask on the substrate, and a maximum thickness of the post-soldering residue is greater than or equal to a maximum thickness of the solder mask.

6. The method of claim 1, wherein the substrate is a semiconductor substrate, a glass substrate, an interposer, or a printed circuit board substrate.

7. The method of claim 1, wherein each solder bump has a diameter of less than or equal to 100 μm.

8. A method for fabricating a semiconductor package, comprising:
applying solder paste comprising a predetermined polymer material onto a substrate;
bringing a plurality of solder bumps on a semiconductor die into contact with the solder paste on the substrate;
reflowing the solder paste to form a plurality of solder joints between the substrate and the semiconductor die; and
applying an underfill comprising the predetermined polymer material between the substrate and the semiconductor die to encapsulate the solder joints.

9. The method of claim 8, wherein the predetermined polymer material comprises epoxy resin.

10. The method of claim 8, wherein a post-soldering residue is produced on the substrate to encapsulate a lower portion of each solder joint after the solder paste is reflowed; the step of applying the underfill between the substrate and the semiconductor die to encapsulate the solder joints comprises:
filling a gap between the semiconductor die and the post-soldering residue with the underfill to encapsulate an upper portion of the solder joint.

11. The method of claim 8, wherein a post-soldering residue is produced on the substrate to encapsulate a portion of each solder joint after the solder paste is reflowed, and the solder joints are formed within an opening of a solder mask on the substrate; within the opening, an area on the substrate between adjacent solder points is covered with the post-soldering residue.

12. The method of claim 8, wherein a post-soldering residue is produced on the substrate to encapsulate a portion of each solder joint after the solder paste is reflowed, and the solder joints are formed within an opening of a solder mask on the substrate; a maximum thickness of the post-soldering residue is greater than or equal to a maximum thickness of the solder mask.

13. The method of claim 8, wherein a post-soldering residue comprising the predetermined polymer material is produced on the substrate to encapsulate a portion of each solder joint after the solder paste is reflowed.

14. The method of claim 8, wherein the substrate is a semiconductor substrate, a glass substrate, an interposer, or a printed circuit board substrate.

15. A semiconductor package, comprising:
a substrate;
a semiconductor die;
a plurality of solder joints electrically connected between the substrate and the semiconductor die;
a post-soldering residue comprising a predetermined polymer material, the post-soldering residue being formed on the substrate to encapsulate a lower portion of each solder joint; and
an underfill comprising the predetermined polymer material, the underfill being formed between the semiconductor die and the post-soldering residue to encapsulate an upper portion of each solder joint.

16. The semiconductor package of claim 15, wherein the predetermined polymer material comprises epoxy resin.

17. The semiconductor package of claim 15, further comprising:
a solder mask, formed on the substrate, wherein the solder joints are located within an opening of the solder mask; within the opening, an area on the substrate between adjacent solder points is covered with the post-soldering residue.

18. The semiconductor package of claim 15, further comprising:
a solder mask, formed on the substrate, wherein the solder joints are located within an opening of the solder mask, and a maximum thickness of the post-soldering residue is greater than or equal to a maximum thickness of the solder mask.

19. The semiconductor package of claim 15, wherein the solder joints are located on a plurality of pads of the semiconductor die respectively, and a distance between adjacent pads is less than or equal to 200 μm.

20. The semiconductor package of claim 15, wherein the substrate is a semiconductor substrate, a glass substrate, an interposer, or a printed circuit board substrate.
